(19) United States
(12) Patent Application Publication
(10) Pub. No.: US 2026/0191079 A1
(43) Pub. Date: Jul. 2, 2026

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventor: Jongbo SHIM, Suwon-si (KR)

(73) Assignee: Samsung Electronics Co., Ltd., Suwon-si (KR)

(21) Appl. No.: 19/417,591

(22) Filed: Dec. 12, 2025

(30) Foreign Application Priority Data
Dec. 30, 2024 (KR) 10-2024-0199641

(51) Int. Cl. H10W 72/00; H10W 70/685; H10W 74/10; H10W 90/00; H10W 90/24

(52) U.S. Cl. CPC H10W 72/823; H10W 70/687; H10W 90/401; H10W 74/117; H10W 90/24; H10W 90/724; H10W 90/734; H10W 90/752; H10W 90/754

(57) ABSTRACT

A semiconductor package semiconductor package includes a package substrate including a first upper protective layer exposing a plurality of first substrate pads in a first region and a plurality of second substrate pads in a second region of the package substrate, a second upper protective layer on the first upper protective layer in the second region of the package substrate, a plurality of bonding pads electrically connected to the plurality of second substrate pads, a semiconductor chip on the first upper protective layer in the first region of the package substrate, conductive connection pins respectively on the plurality of bonding pads, an interposer on the package substrate with the conductive connection pins therebetween, and a molding member covering the semiconductor chip and the conductive connection pins between the package substrate and the interposer.

### PRIORITY STATEMENT

This application claims priority under 35 U.S.C. § 119 to Korean Patent Application No. 10-2024-0199641, filed on Dec. 30, 2024 in the Korean Intellectual Property Office (KIPO), the contents of which are herein incorporated by reference in their entirety.

### BACKGROUND

### 1. Field

Example embodiments relate to a semiconductor package and a method of manufacturing the semiconductor package. More particularly, example embodiments relate to a POP (Package On Package) type semiconductor package in which an upper package is stacked on a lower package and a method of manufacturing the same.

2. Description of the Related Art

Due to the increased demand for higher functionality, higher speed, and greater miniaturization of electronic components (such as mobile products), methods of stacking an upper package on a lower package are being explored for semiconductor packaging technologies. In the lower package of a package on package (PoP) device, solder balls may be interposed between a package substrate and an interposer to support the interposer and electrically connect the interposer and a semiconductor chip on the package substrate. In order to maintain a gap between the package substrate and the interposer greater than a thickness of the semiconductor chip, the sizes of the solder balls and sizes of substrate pads to which the solder balls are bonded may be increased. However, as the sizes of the substrate pads increase, there is a problem that circuit layers must be added or a package size must be increased in order to secure a design routing area.

### SUMMARY

Some example embodiments provide a semiconductor package with improved board-level reliability and improved heat dissipation characteristics.

Some example embodiments provide a method of manufacturing the semiconductor package.

According to some example embodiments, a semiconductor package includes a package substrate including a first upper protective layer exposing a plurality of first substrate pads and a plurality of second substrate pads, the plurality of first substrate pads on an upper surface of the package substrate in a first region and the plurality of second substrate pads on the upper surface of the package substrate in a second region; a second upper protective layer on an upper surface of the first upper protective layer, the second upper protective layer in the second region of the package substrate and exposing the first region of the package substrate, the second upper protective layer including a plurality of bonding pads electrically connected to the plurality of second substrate pads; a semiconductor chip on the first upper protective layer in the first region of the package substrate, the semiconductor chip electrically connected to the plurality of first substrate pads; conductive connection pins respectively on the plurality of bonding pads; an interposer over the package substrate such that the conductive connection pins are between the interposer and the package substrate, the interposer electrically connected to the conductive connection pins; and a molding member between the package substrate and the interposer such that the molding member is covering the semiconductor chip and the conductive connection pins.

According to some example embodiments, a semiconductor package includes a package substrate including a plurality of first substrate pads, a plurality of second substrate pads, and a first upper protective layer, the plurality of first substrate pads on an upper surface of the package substrate in a first region, the plurality of second substrate pads on the upper surface of the package substrate in a second region, and the first upper protective layer exposing the plurality of first substrate pads through first openings and exposing the plurality of second substrate pads through second openings; a second upper protective layer on an upper surface of the first upper protective layer in the second region of the package substrate, the second upper protective layer exposing the second openings through third openings; a plurality of bonding pads respectively in the third openings of the second upper protective layer, the plurality of bonding pads electrically connected to the plurality of second substrate pads; a semiconductor chip on the first upper protective layer in the first region of the package substrate, the semiconductor chip electrically connected to the plurality of first substrate pads; conductive connection pins respectively on the plurality of bonding pads; an interposer over the package substrate such that the conductive connection pins are between the interposer and the package substrate, the interposer electrically connected to the conductive connection pins; and a molding member between the package substrate and the interposer such that the molding member is covering the semiconductor chip and the conductive connection pins

According to some example embodiments, a semiconductor package includes a lower package; an upper package; and conductive connecting members connecting the upper package to the lower package. The lower package comprising a package substrate including a plurality of first substrate pads, a plurality of second substrate pads, and a first upper protective layer, the plurality of first substrate pads on an upper surface of the package substrate in a first region, the plurality of second substrate pads on the upper surface of the package substrate in a second region, and the first upper protective layer exposing the plurality of first substrate pads through first openings and exposing the plurality of second substrate pads through second openings,
a second upper protective layer on the first upper protective layer in the second region of the package substrate, the second upper protective layer exposing the second openings through third openings, a plurality of bonding pads respectively within the third openings and electrically connected to the plurality of second substrate pads, a semiconductor chip on the first upper protective layer within the first region of the package substrate, the semiconductor chip electrically connected to the plurality of first substrate pads, conductive connection pins respectively on the plurality of bonding pads, an interposer over the package substrate such that the conductive connection pins are between the interposer and the package substrate, the interposer electrically connected to the conductive connection pins; and a molding member between the package substrate and the interposer such that the molding member is covering the semiconductor chip and the conductive connection pin.

According to some example embodiments, a semiconductor package may include a semiconductor chip mounted on a first region of a package substrate, a second upper protective layer having a plurality of bonding pads electrically connected to a plurality of second substrate pads on a second region of the package substrate, conductive connection pins respectively disposed on the plurality of bonding pads and electrically connected to the semiconductor chip, and an interposer disposed on the package substrate with the conductive connection pins interposed therebetween.

Since the conductive connection pins have a relatively large height, a gap between the package substrate and the interposer may be increased. Accordingly, by accommodating the semiconductor chip having a relatively large thickness, heat dissipation characteristics may be improved. Further, diameters and pitches of the bonding pads and the second substrate pads may be reduced to facilitate circuit routing design.

### BRIEF DESCRIPTION OF THE DRAWINGS

Some example embodiments will be more clearly understood from the following detailed description taken in conjunction with the accompanying drawings. FIGS. 1 to 22 represent non-limiting, some example embodiments as described herein.

FIG. 1 is a cross-sectional view illustrating a semiconductor package in accordance with some example embodiments.

FIG. 2 is an enlarged cross-sectional view illustrating portion ‘A1” in FIG. 1.

FIG. 3 is a plan view illustrating a second upper protective layer of a lower package in FIG. 1.

FIGS. 4 to 18 are views illustrating a method of manufacturing a semiconductor package in accordance with some example embodiments.

FIG. 19 is a cross-sectional view illustrating a portion of a semiconductor package in accordance with some example embodiments.

FIG. 20 is a plan view illustrating a semiconductor package in accordance with some example embodiments.

FIG. 21 is an enlarged cross-sectional view illustrating portion ‘A1’ in FIG. 20.

FIG. 22 is a cross-sectional view illustrating a semiconductor package in accordance with some example embodiments.

### DETAILED DESCRIPTION OF SOME EXAMPLE EMBODIMENTS

Hereinafter, some example embodiments will be explained in detail with reference to the accompanying drawings. In the following drawings, the same reference numerals refer to the same components, and the size of each component in the drawings may be exaggerated for clarity and convenience of description. In addition, the embodiments described below are merely examples and various modifications are possible from these embodiments.

When, the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. Additionally, in all figures in this specification, directions indicated by an arrow and a reverse direction thereto are considered as the same direction. Additionally, whenever a range of values is enumerated, the range includes all values within the range as if recorded explicitly clearly, and may further include the boundaries of the range. Accordingly, the range of “X” to “Y” includes all values between X and Y, including X and Y.

Hereinafter, terms “upper” or “top” or “lower” or “bottom” may include not only those directly above/below/left/right in contact, but also those above/below/left/right without contact. It will also be understood that such spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly. The singular expression includes plural expressions unless the context clearly implies otherwise. In addition, when a part “includes” a component, this means that it may further include other components, not excluding other components unless otherwise stated.

Also, terms, such as “unit”, “portion”, and “module”, and/or terms describing a unit that processes at least one function or operation, may be implemented by processing circuitry, such as hardware, software, or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components.

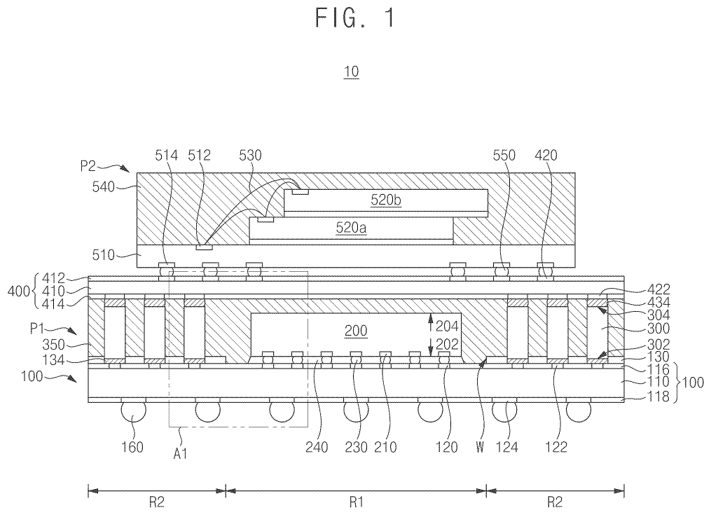

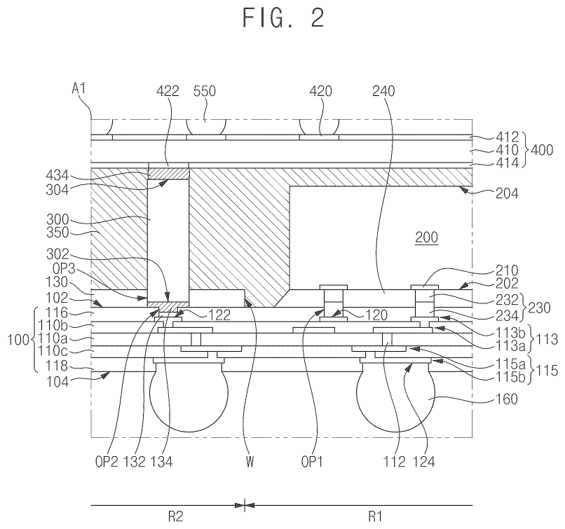

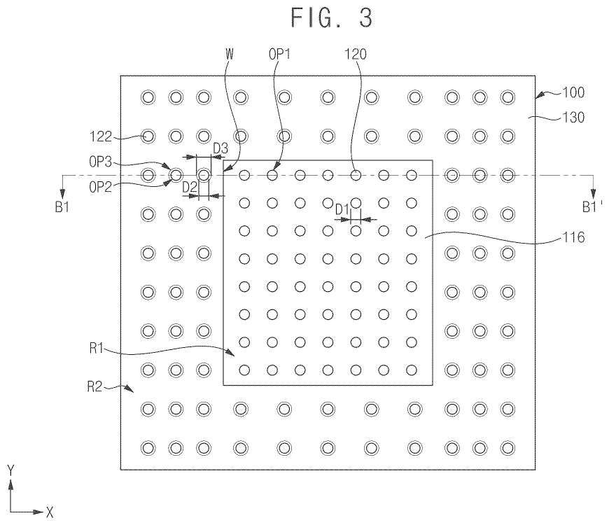

FIG. 1 is a cross-sectional view illustrating a semiconductor package in accordance with some example embodiments. FIG. 2 is an enlarged cross-sectional view illustrating portion ‘A1” in FIG. 1. FIG. 3 is a plan view illustrating a second upper protective layer of a lower package in FIG. 1. FIG. 3 is a plan view illustrating the lower package in FIG. 2, wherein a semiconductor chip, a molding member and an interposer are omitted. FIG. 1 includes a cross-sectional portion cut along the line B1-B1′ in FIG. 3.

Referring to FIGS. 1 to 3, a semiconductor package 10 may include a lower package P1 and an upper package P2 stacked on the lower package P1 using conductive connection members 550. Additionally, the semiconductor package 10 may further include external connection members 160 provided on a lower surface of the lower package P1.

Additionally, the semiconductor package 10 may be a multi-chip package (MCP) including different types of semiconductor chips. The semiconductor package 10 may be a system in package (SIP) including a plurality of semiconductor chips (for example, a memory chip and a logic chip) that perform multiple functions in one package.

In some example embodiments, the lower package P1 may include a first package substrate 100, at least one first semiconductor chip 200 mounted on the first package substrate 100, conductive connection pins 300 disposed on the first package substrate 100 and electrically connected to the at least one first semiconductor chip 200, an interposer 400 disposed on the first package substrate 100 with the conductive connection pins 300 interposed therebetween and electrically connected to the conductive connection pins 300, and a molding member 350 covering the first semiconductor chip 200 and the conductive connection pins 300 between the first package substrate 100 and the interposer 400.

The first package substrate 100 may be a substrate having an upper surface 102 and a lower surface 104 opposite to the upper surface 102. For example, the first package substrate 100 may be and/or include a printed circuit board (PCB), a flexible substrate, a tape substrate, etc. The printed circuit board may be a multilayer circuit board having vias and various circuits therein. Alternatively, the first package substrate 100 may include a coreless substrate or a redistribution wiring layer.

The first package substrate 100 may include a plurality of stacked insulating layers 110 and wirings 113, 115 provided in the insulating layers. The wirings may include internal wirings that serve as channels for electrical connection with the first semiconductor chip.

In particular, the first package substrate 100 may include a core layer 110a, an upper insulating layer 110b on an upper surface of the core layer 110a, and a lower insulating layer 110c on a lower surface of the core layer 110a. The first package substrate 100 may include a plurality of through vias 112 penetrating the core layer 110a, first upper circuit wirings 113a on the upper surface of the core layer 110a, second upper circuit wirings 113b provided in the upper insulating layer 110b, first lower circuit wirings 115a on the lower surface of the core layer 110a, and second lower circuit wirings 115b provided in the lower insulating layer 110c.

In some example embodiments, the first package substrate 100 may include a first upper protective layer 116 on an upper surface of the upper insulating layer 110b to cover the second upper circuit wirings 113b and a lower protective layer 118 on a lower surface of the lower insulating layer 110c to cover the second lower circuit wirings 115b. An upper surface of the first upper protective layer 116 may be provided as the upper surface 102 of the first package substrate 100, and a lower surface of the lower protective layer 118 may be provided as the lower surface 104 of the first package substrate 100.

The first upper protective layer 116 may expose portions of the second upper circuit wirings 113b. The exposed portions of the second upper circuit wirings 113b may be provided as upper substrate pads 120, 122. The lower protective layer 118 may expose portions of the second lower circuit wirings 115b. The exposed portions of the second lower circuit wirings 115b may be provided as lower substrate pads 124.

In some example embodiments, the first package substrate 100 may include a plurality of first substrate pads 120 arranged within the first region R1 and a plurality of second substrate pads 122 arranged within the second region R2. The first substrate pads 120 may be arranged in a form of an array within the first region R1.

A second upper protective layer 130 may be provided on the first upper protective layer 116 in the second region R2 of the first package substrate 100. A plurality of bonding pads 134 may be provided in the second upper protective layer 130 to be electrically connected to the plurality of second substrate pads 122 respectively. The second upper protective layer 130 may have a window W that exposes the first region R1, and may cover the entire second region R2 of the package substrate.

As illustrated in FIGS. 2 and 3, the first upper protective layer 116 may have first openings OP1 that respectively expose the plurality of first substrate pads 120 and second openings OP2 that respectively expose the plurality of second substrate pads 122. The second upper protective layer 130 may have third openings OP3 that respectively expose the second openings OP2. Each of the first openings OP1 may have a first diameter D1 and each of the second openings OP2 may have a second diameter D2. Each of the third openings OP3 may have a third diameter D3. For example, the second diameter D2 may be the same as or substantially similar to the first diameter D1. The first and second diameters D1, D2 may be within a range of 25 micrometers (μm) to 60 μm. Alternatively, the second diameter D2 may be greater than the first diameter D1. The third diameter D3 may be greater than the second diameter D2. The third diameter D3 may be within a range of 40 μm to 90 μm.

For example, thicknesses of the first upper protective layer 116, the second upper protective layer 130 and the lower protective layer 118 in a stacking direction may be within a range of 10 μm to 30 μm. The first upper protective layer 116, the second upper protective layer 130 and the lower protective layer 118 may include an organic insulator. For example, in at least some embodiments, the organic insulator may be (or include) at least one of a photosensitive resin (such as photo epoxy), a photosensitive polymer (such as photosensitive polyimide (PSPI), photo solder resist (PSR), etc.), and/or the like.

In some example embodiments, conductive posts 132 may be respectively provided in the second openings OP2 of the first upper protective layer 116. Bonding pads 134 may be respectively provided on the conductive posts 132. The conductive posts 132 may include a first conductive material, such as metal material, and the bonding pads 134 may include a second conductive material, such as a second metal material different from the first metal material. In at least some example embodiments, the first conductive material may be, for example, copper (Cu), and the second metal material may be a eutectic alloy, such as solder, having a lower flow temperature compared to the first metal material.

The conductive posts 132 may fill a lower portion of the second opening OP2 and may be in contact with the second substrate pad 122. The bonding pad 134 may completely fill the second opening OP2 and may be in contact with the conductive post 132. The bonding pad 134 may be formed to fill the lower portion of the third opening OP3.

In some example embodiments, the first semiconductor chip 200 may be mounted on the first region of the first package substrate 100 via conductive bumps 230. The first semiconductor chip 200 may be disposed such that a first surface 202 (e.g., an “active surface”) on which first chip pads 210 are formed faces the first package substrate 100. The first semiconductor chip 200 may have a rectangular shape with four sides when viewed in a plan view. The first chip pads 210 may be arranged in a form of array over the entire first surface 202 of the first semiconductor chip 200. The first semiconductor chip 200 may receive and/or transmit signals to second substrate pad 122 and/or the lower substrate pads 124 using electrical paths formed by the wirings 113, 115.

In at least some example embodiments, the first semiconductor chip 200 may be a logic chip including logic circuits. The logic chip may be a controller including processing circuitry configured to control memory chips. The first semiconductor chip may be, for example, a processor chip such as ASIC and/or an application processor AP configured as a host such as a CPU, a GPU, and/or a SOC.

The first semiconductor chip 200 may be mounted on the first package substrate 100 using a flip chip bonding method. The chip pads 210 of the first semiconductor chip 200 may be electrically connected to the first substrate pads 120 of the first package substrate 100 through the conductive bumps 230. For example, the conductive bump 230 may include a pillar bump 232 formed on the first chip pad 210 and a solder bump 234 formed on the pillar bump 232. The solder bump 234 may be arranged within the first opening OP1 of the first upper protective layer 116 and may be bonded to the first substrate pad 120 of the first package substrate 100. A thickness of the first semiconductor chip 200 in the stacking direction may be within a range of 150 μm to 300 μm. As described below, the conductive connection pins 300 may be formed to have a high aspect ratio, so that the first semiconductor chip 200 having a relatively large thickness may be mounted.

Additionally, an underfill member 240 may be underfilled between the first semiconductor chip 200 and the first package substrate 100. The underfill member may include a material with relatively high fluidity to effectively fill a small space between the first semiconductor chip and the first package substrate. For example, in at least some example embodiments, the underfill member may include an adhesive containing an epoxy material.

In some example embodiments, the conductive connection pins 300 may be bonded onto the bonding pads 134 in the second region R2 of the first package substrate 100.

A first end portion 302 of the conductive connection pin 300 may be arranged to be accommodated within the third opening OP3 of the second upper protective layer. The conductive connection pins 300 may be respectively bonded to the bonding pads 134 by a reflow process. Since the bonding pad 134 includes a solder material, the first end portion 302 of the conductive connection pin 300 may be bonded to the bonding pad 134 relatively easily. Accordingly, the conductive connection pin 300 may be stably fixed onto the bonding pad 134 within the third opening OP3 of the second upper protective layer. For example, the conductive connection pin 300 may have an aspect ratio (height (H)/diameter (L)) of 3 to 5. A height of the conductive connection pin 300 from the upper surface 102 of the first package substrate 100 may be greater than or equal to a height of the first semiconductor chip 200 from the upper surface 102 of the first package substrate 100.

The interposer 400 may be placed on the first package substrate 100 with the conductive connection pins 300 interposed between the interpose 400 and the first package substrate 100, and may be electrically connected to the conductive connection pins 300. The molding member 350 may cover the first semiconductor chip 200 and the conductive connection pins 300 between the first package substrate 100 and the interposer 400.

The molding member 350 may expose second end portions 304 of the conductive connection pins 300. The molding member 350 may include an epoxy mold compound (EMC).

The interposer 400 may be placed on the molding member 350. The interposer 400 may be, for example, a silicon interposer or a redistribution wiring interposer having a plurality of wirings formed therein. For example, the interposer 400 may include a plurality of insulating layers 410, 412, 414 and wirings provided in the insulating layers. Upper interposer pads 420 may be exposed from an upper surface of the interposer 400. An upper insulating layer 412 may expose at least portions of the upper interposer pads 432. Lower interposer pads 422 may be exposed from a lower surface of the interposer 400. A lower insulating layer 414 may expose at least portions of the lower interposer pads 422. The interposer 400 may be configured to provide signals between the upper interposer pads 420 and corresponding lower interposer pads 422, through electrical paths formed by the wiring in the interposer 400.

Bonding members 434 may be provided on the lower interposer pads 422, respectively. The bonding member 434 may extend in a vertical direction from the lower interposer pad 422. The bonding members 434 may include, e.g., a conductive eutectic alloy with a flow temperature lower than the lower interposer pads 422. For example, the bonding members 434 may include a solder material such as a solder ball.

The bonding members 434 on the lower interposer pads 422 of the interposer 400 may be respectively bonded to the second end portions 304 of the conductive connection pins 300 exposed by the molding member 350. The bonding members 434 may be bonded to the conductive connection pins 300 by a reflow process. The interposer 400 may be electrically connected to the first package substrate 100 by the conductive connection pins 300.

Accordingly, the interposer 400 may be supported on the first package substrate 100 by the conductive connection pins 300, and the lower surface of the interposer 400 may be spaced apart from a backside surface 204 of the first semiconductor chip 200 and the upper surface 102 of the first package substrate 100, to form a space between the first package substrate 100 and the interposer 400.

The conductive connection pins 300 having a relatively large aspect ratio may be stably fixed on the bonding pads 134 to support the interposer 400. The bonding pads 134 within the third openings OP3 of the second upper protective layer may fix the conductive connection pins 300 having a relatively small diameter and a large aspect ratio. Since the conductive connection pins 300 have a relatively large height, the gap between the first package substrate 100 and the interposer 400 may be increased. Accordingly, by accommodating the first semiconductor chip 200 having a relatively large thickness, heat dissipation characteristics may be improved. Further, the diameters and pitches of the bonding pads 134 and the second substrate pads 122 may be reduced to facilitate circuit routing design.

In some example embodiments, an upper package P2 may be stacked on the lower package P1 via conductive connection members 550.

The upper package P2 may include a second package substrate 510, at least one second semiconductor chip 520a, 520b mounted on an upper surface of the second package substrate 510, second conductive connection members 530 electrically connecting second chip pads 522a and 522b of the at least one second semiconductor chip 520a, 520b to upper substrate pads 512 on the upper surface of the second package substrate 510, and a second molding member 540 covering the at least one second semiconductor chip 520a and 520b on the second package substrate 510.

A plurality of the second semiconductor chips 520a and 520b may be sequentially stacked on the second package substrate 510 using adhesive members. Bonding wires as the second conductive connection members 530 may connect the second chip pads 522a and 522b of the second semiconductor chips 520a and 520b to the upper substrate pads 512 of the second package substrate 510.

Although the upper package P2 includes two semiconductor chips mounted using a wire bonding method, it will be understood that the number and mounting method of the second semiconductor chips in the upper package is not limited to the illustrated example. For example, the upper package P2 may include more than two or fewer than two second semiconductor chips.

The second semiconductor chips 520a and 520b may include memory chips including memory circuits. For example, at least one of the second semiconductor chips 520a and 520b may include volatile memory devices such as random access memory (RAM) devices, static RAM (SRAM) devices, dynamic RAM (DRAM) devices, etc., and/or non-volatile memory devices such as flash memory devices, phase-change RAM (PRAM) devices, magneto-resistance RAM (MRAM) devices, or resistance RAM (RRAM) devices, etc.

The conductive connection members 550 may be interposed between the lower package P1 and the upper package P2 to electrically connect them. A gap may be formed between the upper package P2 and the lower package P1 by the conductive connection members 550. The conductive connection members 550 formed on the lower substrate pads 514 of the second package substrate 510 of the upper package P2 may be bonded to the upper interposer pads 420 of the interposer 400.

Although it is not illustrated in the figures, in at least some embodiments, an underfill member may be formed between the lower package P1 and the upper package P2. For example, while moving a dispenser nozzle along one side of the upper package P2, a liquid underfill aqueous solution may be dispensed into the gap between the lower package P2 and the upper package P1. For example, the aqueous underfill solution may include an epoxy material. The underfill aqueous solution may flow to the gap between the lower package P1 and the upper package P2 and then harden to form the underfill member.

In some example embodiments, the external connection members 160 for electrical connection with an external device may be disposed on the lower substrate pads 124 on the lower surface 104 of the first package substrate 100. For example, the external connection member 160 may be a solder ball. The semiconductor package 10 may be mounted on a module substrate (not illustrated) using the solder balls to form a semiconductor module.

As mentioned above, the semiconductor package 10 may include the lower package P1 and the upper package P2 stacked on the lower package P1 via the conductive connection members 550. The lower package P1 may include the first semiconductor chip 200 mounted on the first region R1 of the first package substrate 100, the second upper protective layer 130 having the plurality of bonding pads 134 electrically connected to the plurality of second substrate pads 122 on the second region R2 of the first package substrate 100, the conductive connection pins 300 respectively disposed on the plurality of bonding pads 134 and electrically connected to the first semiconductor chip 200, and the interposer 400 disposed on the first package substrate 100 with the conductive connection pins 300 interposed therebetween and electrically connected to the conductive connection pins 300.

Since the conductive connection pins 300 have a relatively large height, the gap between the first package substrate 100 and the interposer 400 may be increased. Accordingly, by accommodating the first semiconductor chip 200 having a relatively large thickness, heat dissipation characteristics may be improved. Further, the diameters and pitches of the bonding pads 134 and the second substrate pads 122 may be reduced to facilitate circuit routing design.

Hereinafter, a method of manufacturing the semiconductor package of FIG. 1 will be described.

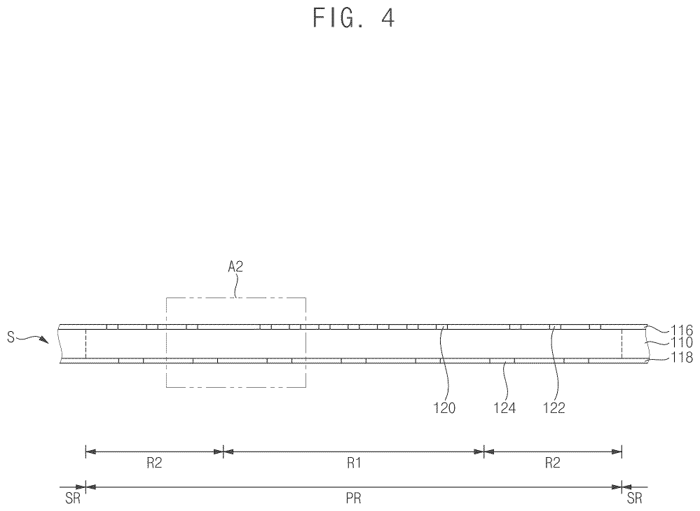

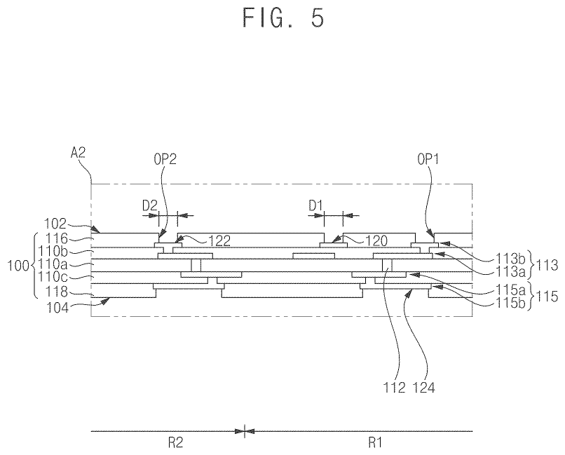

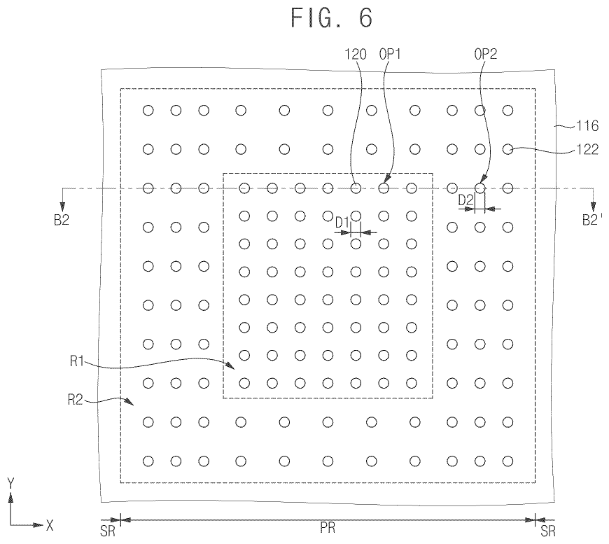

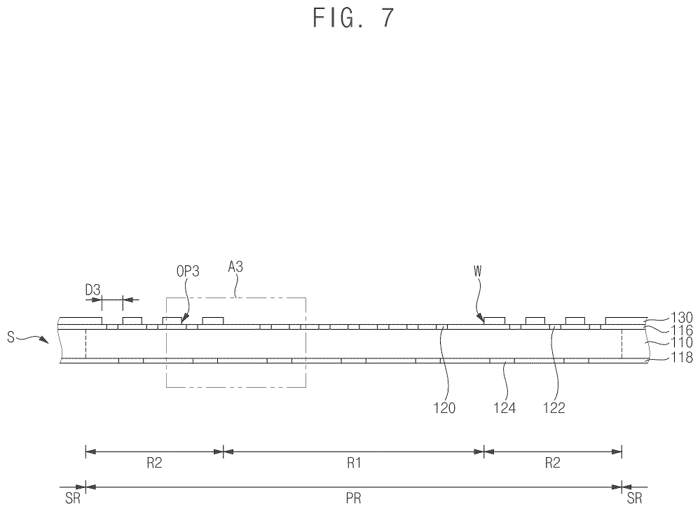

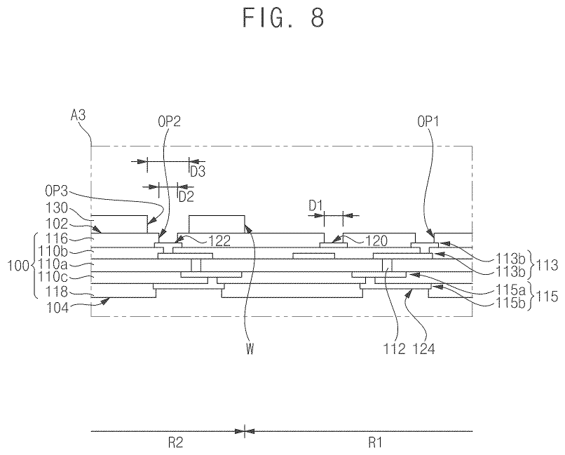

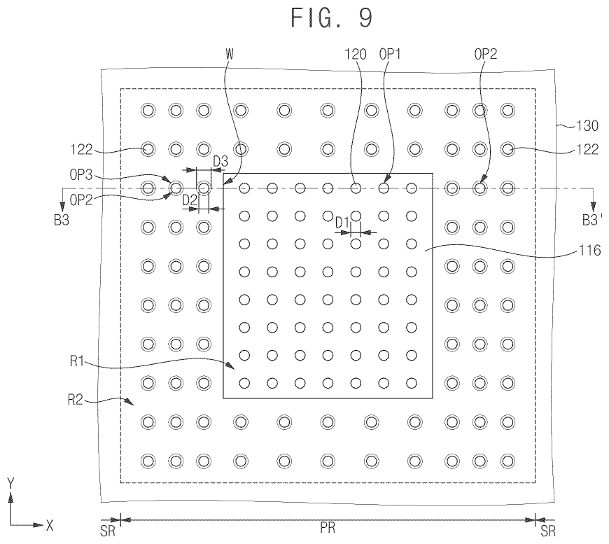

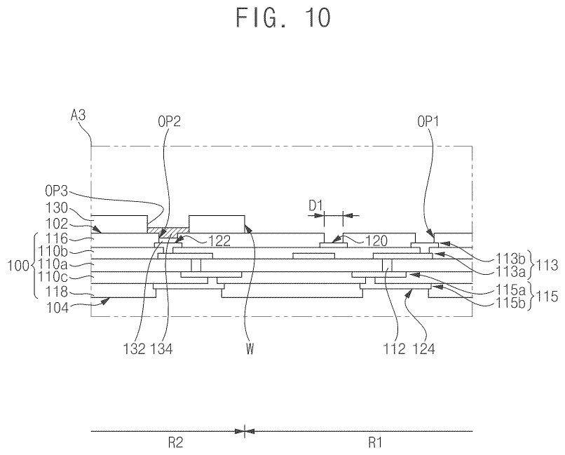

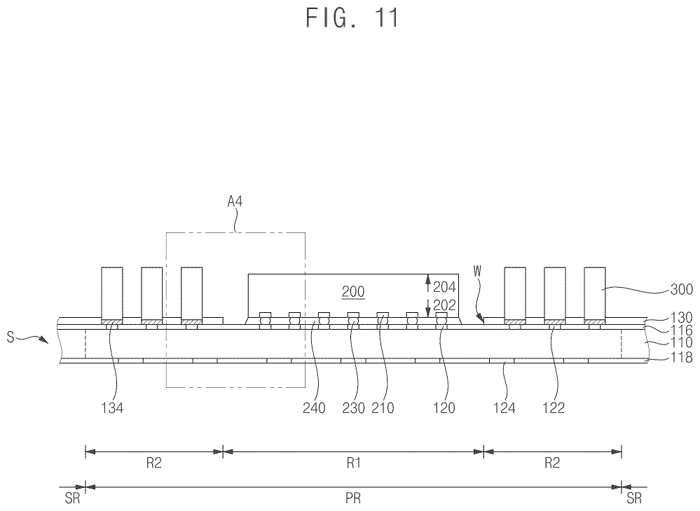

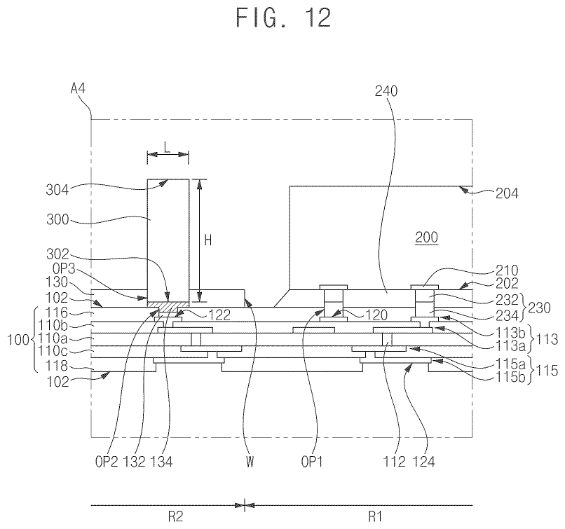

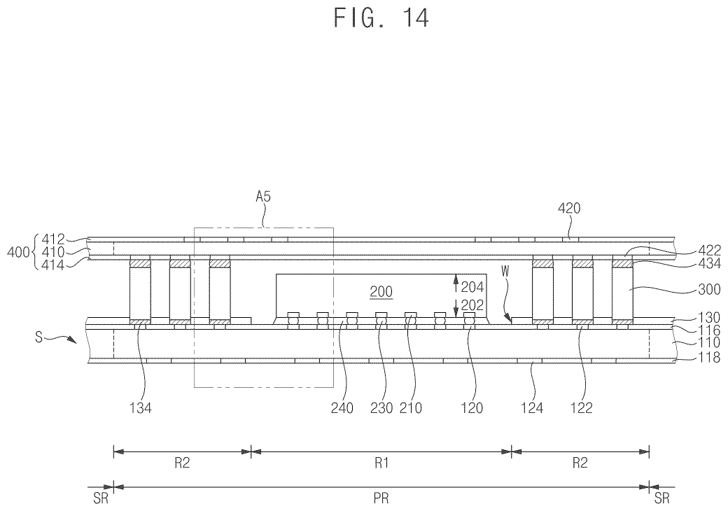

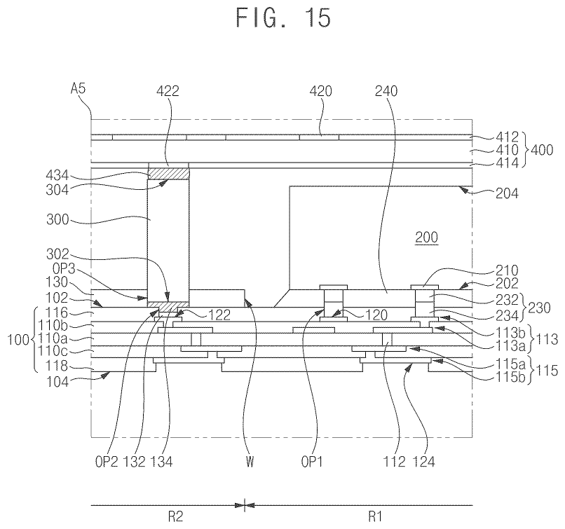

FIGS. 4 to 18 are views illustrating a method of manufacturing a semiconductor package in accordance with some example embodiments. FIGS. 4, 7, 11, 13, 14, 16 and 18 are cross-sectional views illustrating a method of manufacturing a semiconductor package in accordance with some example embodiments. FIG. 5 is an enlarged cross-sectional view illustrating portion ‘A2’ in FIG. 4. FIG. 6 is a plan view of FIG. 4. FIGS. 8 and 10 are enlarged cross-sectional views illustrating portion ‘A3’ in FIG. 7. FIG. 9 is a plan view of FIG. 7. FIG. 12 is an enlarged cross-sectional view illustrating portion ‘A4’ in FIG. 11. FIG. 15 is an enlarged cross-sectional view illustrating portion ‘A5’ in FIG. 14. FIG. 4 is a cross-sectional view taken along the line B2-B2′ in FIG. 6. FIG. 7 is a cross-sectional view taken along the line B3-B3′ in FIG. 9.

Referring to FIG. 4, a substrate S including package substrates 100 formed therein may be provided.

In some example embodiments, the substrate S may be a multilayer circuit board having an upper surface 102 and a lower surface 104 opposite to the upper surface 102. In at least some example embodiments, the substrate S may be a strip substrate for manufacturing a semiconductor strip, such as a printed circuit board (PCB). For example, the substrate S may be and/or include a printed circuit board (PCB), a flexible substrate, a tape substrate, etc. The printed circuit board may be a multilayer circuit board having vias and various circuits therein.

The substrate S may include a package region PR on which a semiconductor chip is mounted and a scribe region SR surrounding the package region PR. As will be described later, after a plurality of semiconductor chips are respectively disposed on the package regions PR of the substrate S, the substrate S may be cut along the scribe region SR that divides the package region PR to be individualized into package substrates.

The substrate S may include a plurality of stacked insulating layers 110 and wirings provided in the insulating layers. The wirings may include internal wirings that serve as channels for electrical connection with the semiconductor chip.

In particular, the first package substrate 100 may include a core layer 110a, an upper insulating layer 110b on an upper surface of the core layer 110a, and a lower insulating layer 110c on a lower surface of the core layer 110a. The upper insulating layer 110b may be provided as an uppermost insulating layer among the plurality of insulating layers 110a, 110b, 110c. The lower insulating layer 110c may be provided as a lowermost insulating layer among the plurality of insulating layers 110a, 110b, 110c.

The first package substrate 100 may include a plurality of through vias 112 penetrating the core layer 110a, first upper circuit wirings 113a on the upper surface of the core layer 110a, second upper circuit wirings 113b provided in the upper insulating layer 110b, first lower circuit wirings 115a on the lower surface of the core layer 110a, and second lower circuit wirings 115b provided in the lower insulating layer 110c. The through vias 112 may be (or include) a conductive material, such as copper (Cu).

For example, the insulating layer may include an insulating material such as a thermosetting resin such as epoxy resin or a thermoplastic resin such as polyimide. The insulating layer may include a resin impregnated in a core material such as organic fiber (glass fiber), for example, a prepreg, FR-4, BT (Bismaleimide Triazine), etc.

The first package substrate 100 may include a first region R1 and a second region R2. The second region R2 may be provided adjacent to the first region R1. The second region R2 may be provided to surround the first region R1. The first region R1 may be provided as a region where the semiconductor chip is mounted, and the second region R2 may be provided as a region where a plurality of conductive connection pins are arranged. The first region R1 may have a rectangular shape.

In some example embodiments, the first package substrate 100 may include a first upper protective layer 116 on the upper surface of the upper insulating layer 110b to cover the second upper circuit wirings 113b and a lower protective layer 118 on the lower surface of the lower insulating layer 110c to cover the second lower circuit wirings 115b. An upper surface of the first upper protective layer 116 may be provided as the upper surface 102 of the first package substrate 100, and a lower surface of the lower protective layer 118 may be provided as the lower surface 104 of the first package substrate 100.

The first upper protective layer 116 may expose portions of the second upper circuit wirings 113b. The exposed portions of the second upper circuit wirings 113b may be provided as upper substrate pads 120, 122. The lower protective layer 118 may expose portions of the second lower circuit wirings 115b. The exposed portions of the second lower circuit wirings 115b may be provided as lower substrate pads 124.

In some example embodiments, the first package substrate 100 may include a plurality of first substrate pads 120 arranged within the first region R1 and a plurality of second substrate pads 122 arranged within the second region R2. The first substrate pads 120 may be arranged in a form of an array within the first region R1.

As illustrated in FIGS. 5 and 6, the first upper protective layer 116 may have first openings OP1 that respectively expose the plurality of first substrate pads 120 and second openings OP2 that respectively expose the plurality of second substrate pads 122. Each of the first openings OP1 may have a first diameter D1 and each of the second openings OP2 may have a second diameter D2. For example, the second diameter D2 may be the same as (or substantially similar to) the first diameter D1. The first and second diameters D1, D2 may be within a range of 25 μm to 60 μm (e.g., 25 μm≤D1, D2≤60 μm). Alternatively, the second diameter D2 may be greater than the first diameter D1 (e.g., D1≤D2).

For example, thicknesses of the first upper protective layer 116 and the lower protective layer 118 may be within a range of 10 μm to 30 μm. The first upper protective layer 116 and the lower protective layer 118 may include a photosensitive resin such as photo epoxy, a photosensitive polymer such as photosensitive polyimide (PSPI), photo solder resist (PSR), etc.

Referring to FIGS. 7 to 10, a second upper protective layer 130 may be formed on the first upper protective layer 116 in the second region R2 of the substrate S, and a plurality of bonding pads 134 may be formed in the second upper protective layer 130 to be electrically connected to the plurality of second substrate pads 122 respectively.

As illustrated in FIGS. 7 to 9, a solder resist layer may be formed on the upper surface of the first upper protective layer 116, and exposure and development processes may be performed to form the second upper protective layer 130 from the solder resist layer such that the second upper protective layer 130 has a window W and third openings OP3 that respectively expose the second openings OP2.

The second upper protective layer 130 may have the window W that exposes the first region R1, and may cover the entire second region R2 of the package substrate. Each of the third openings OP3 may have a third diameter D3. For example, the third diameter D3 may be greater than the second diameter D2. The third diameter D3 may be within a range of 40 μm to 90 μm. A thickness of the second upper protective layer 130 may be within a range of 10 μm to 30 μm. The second upper protective layer 130 may include a photosensitive resin such as photo epoxy, or a photosensitive polymer such as photosensitive polyimide (PSPI), photo solder resist (PSR), etc.

Then, as illustrated in FIG. 10, the bonding pads 134 may be respectively arranged in the third openings OP3 of the second upper protective layer.

In some example embodiments, conductive posts 132 may be respectively formed in the second openings OP2 of the first upper protective layer 116, and the bonding pads 134 may be respectively formed on the conductive posts 132. The conductive posts 132 and the bonding pads 134 may be formed by a plating process, a deposition process, etc. The conductive posts 132 may include a first metal material such as copper (Cu), and the bonding pads 134 may include a second metal material such as solder.

The conductive posts 132 may fill a lower portion of the second opening OP2 and may be in contact with the second substrate pad 122. The bonding pad 134 may completely fill the second opening OP2 and make contact with the conductive post 132. The bonding pad 134 may be formed to fill the lower portion of the third opening OP3.

Referring to FIGS. 11 and 12, at least one first semiconductor chip 200 may be mounted on the first region R1 of the substrate S and conductive connection pins 300 may be respectively disposed on the bonding pads 134 in the second region R2 of the substrate S.

In some example embodiments, the first semiconductor chip 200 may be mounted on the first region R1 of the substrate S via conductive bumps 230. The first semiconductor chip 200 may be disposed such that a first surface 202 on which chip pads 210 are formed, that is, an active surface, faces the substrate S. The first semiconductor chip 200 may have a rectangular shape with four sides when viewed in the plan view. The chip pads 210 may be arranged in a form of array over the entire first surface 202 of the first semiconductor chip 200.

The first semiconductor chip 200 may be a logic chip including logic circuits. The logic chip may be a controller that is configured to control memory chips.

The first semiconductor chip 200 may be mounted on the substrate S using a flip chip bonding method. The chip pads 210 of the first semiconductor chip 200 may be electrically connected to the first substrate pads 120 of the substrate S through the conductive bumps 230. For example, the conductive bump 230 may include a pillar bump 232 formed on the chip pad 210 and a solder bump 234 formed on the pillar bump 232. The solder bump 234 may be arranged within the first opening OP1 of the first upper protective layer 116 and may be bonded to the first substrate pad 120 of the substrate S. A thickness of the first semiconductor chip 200 may be within a range of 150 μm to 300 μm. As described below, the conductive connection pins 300 may be formed to have a high aspect ratio, so that the first semiconductor chip 200 having a relatively large thickness may be mounted.

Additionally, an underfill member 240 may be underfilled between the first semiconductor chip 200 and the substrate S. The underfill member may include a material with relatively high fluidity to effectively fill a small space between the semiconductor chip and the substrate. For example, the underfill member may include an adhesive containing an epoxy material.

Then, the conductive connection pins 300 having a selected aspect ratio may be formed, and the conductive connection pins 300 may be bonded onto the bonding pads 134 in the second region R2 of the substrate S. In at least some embodiments, the conductive connection pins 300 may be transferred onto the conductive connection pins 300. In these cases, the crystal orientation of the conductive connection pins 300 may be misaligned with the crystal orientation of the second substrate pads 122.

A first end portion 302 of the conductive connection pin 300 may be arranged to be accommodated within the third opening OP3 of the second upper protective layer. The conductive connection pins 300 may be bonded to the bonding pads 134 respectively by a reflow process. Since the bonding pad 134 includes a solder material, the first end portion 302 of the conductive connection pin 300 may be easily bonded to the bonding pad 134. Accordingly, the conductive connection pin 300 may be stably fixed onto the bonding pad 134 within the third opening OP3 of the second upper protective layer. For example, the conductive connection pin 300 may have an aspect ratio (H/L) of 3 to 5.

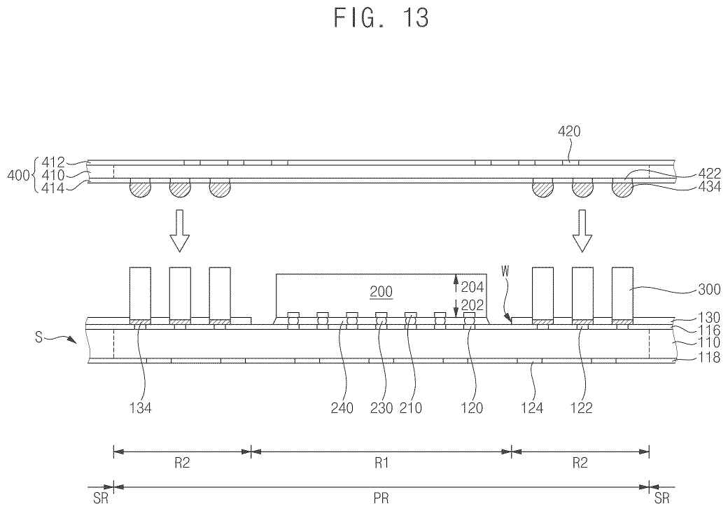

Referring to FIGS. 13 to 15, an interposer 400 may be disposed on the substrate S via the conductive connection pins 300 therebetween.

As illustrated in FIG. 13, bonding members 434 may be formed on lower interposer pads 422 on a lower surface of the interposer 400, and the interposer 400 may be placed on the substrate S such that the bonding members 434 face the substrate S.

The interposer 400 may be a silicon interposer or a redistribution wiring interposer having a plurality of wirings formed therein. For example, the interposer 400 may include a plurality of insulating layers 410, 412, and 414 and the wirings provided in the insulating layers. Upper interposer pads 420 may be exposed from an upper surface of the interposer 400. An upper insulating layer 412 may expose at least portions of the upper interposer pads 432. The lower interposer pads 422 may be exposed from a lower surface of the interposer 400. A lower insulating layer 414 may expose at least portions of the lower interposer pads 422.

The bonding members 343 may be formed on the lower interposer pads 422, respectively. The bonding member 343 may extend in a vertical direction from the lower interposer pad 422. The bonding members 343 may include a solder material such as a solder ball.

As illustrated in FIGS. 14 and 15, the bonding members 343 may be respectively placed on the conductive connection pins 300 on the substrate S by a solder ball attach process. The bonding members 343 on the interposer 400 may be thermally compressed on second end portions 304 of the conductive connection pins 300 on the substrate S respectively. The bonding members 343 may be bonded to the conductive connection pins 300 through a reflow process. The interposer 400 may be electrically connected to the package substrate by the conductive connection pins 300.

Accordingly, the interposer 400 may be supported on the substrate S by the conductive connection pins 300, and the lower surface of the interposer 400 may be spaced apart from the backside surface 204 of the first semiconductor chip 200 and the upper surface 102 of the substrate S, to form a space between the substrate S and the interposer 400.

The conductive connection pins 300 having a relatively large aspect ratio may be stably fixed on the bonding pads 134 to support the interposer 400. The bonding pads 134 within the third openings OP3 of the second upper protective layer may fix the conductive connection pins 300 having a relatively small diameter and a large aspect ratio. Since the conductive connection pins 300 have a relatively large height, the gap between the substrate S and the interposer 400 may be increased. Accordingly, by accommodating the first semiconductor chip 200 having a relatively large thickness, heat dissipation characteristics may be improved.

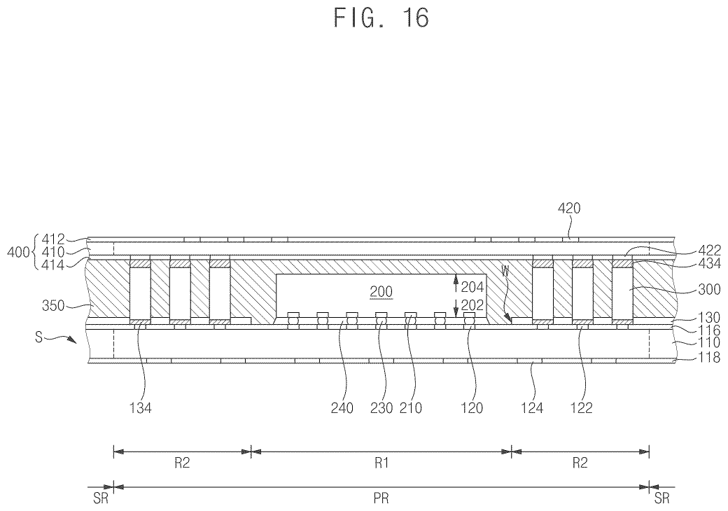

Referring to FIG. 16, a first sealing member 350 be formed between the substrate S and the interposer 400 to cover the first semiconductor chip 200 and the conductive connection pins 300.

For example, a molding material may be injected between the substrate S and the interposer 400 by a transfer molding process to form the molding member 350 covering the first semiconductor chip 200 and the conductive connection pins 300. The molding member 350 may fill spaces between the conductive connection pins 300. The molding member 350 may include an epoxy mold compound EMC. The molding member 350 may include UV resin, polyurethane resin, silicone resin, silica fillers, etc.

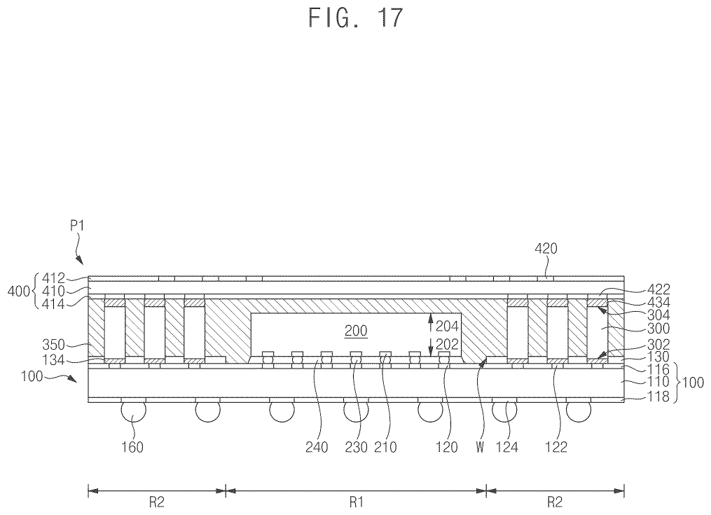

Referring to FIG. 17, external connection members 160 may be disposed on the lower substrate pads 124 on the lower surface 104 of the substrate S, and the substrate S may be diced to form individual lower packages P1.

In some example embodiments, solder balls as the external connection members may be disposed on the lower substrate pads 124 on the lower surface 104 of the substrate S. Then, the substrate S may be cut along the scribe region SR dividing the plurality of package regions PR by a sawing process to be individualized into a plurality of the lower packages P1.

The lower package P1 may include the first package substrate 100, the first semiconductor chip 200 mounted on the first region R1 of the first package substrate 100, the second upper protective layer 130 having the plurality of bonding pads 134 electrically connected to the plurality of second substrate pads 122 on the second region R2, the conductive connection pins 300 respectively disposed on the plurality of bonding pads 134 and electrically connected to the first semiconductor chip 200, the interposer 400 disposed on the first package substrate 100 with the conductive connection pins 300 interposed therebetween and electrically connected to the conductive connection pins 300, and the molding member 350 covering the first semiconductor chip 200 and the conductive connection pins 300 between the first package substrate 100 and the interposer 400.

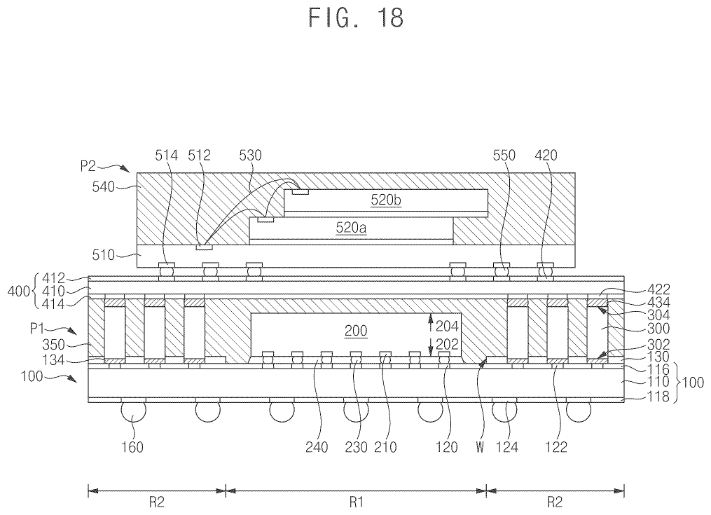

Referring to FIG. 18, an upper package P2 may be stacked on the lower package P1 via conductive connection members 550.

In some example embodiments, the upper package P2 may include a second package substrate 510, at least one second semiconductor chip 520a, 520b mounted on an upper surface of the second package substrate 510, second conductive connection members 530 electrically connecting second chip pads 522a and 522b of the at least one second semiconductor chip 520a, 520b to upper substrate pads 512 on the upper surface of the second package substrate 510, and a second molding member 540 covering the at least one second semiconductor chip 520a and 520b on the second package substrate 510.

A plurality of the second semiconductor chips 520a and 520b may be sequentially stacked on the second package substrate 510 using adhesive members. Bonding wires as the second conductive connection members 530 may connect the second chip pads 522a and 522b of the second semiconductor chips 520a and 520b to the upper substrate pads 512 of the second package substrate 510.

Although the upper package P2 includes two semiconductor chips mounted using a wire bonding method, it will be understood that the number and mounting method of the second semiconductor chips in the upper package may not be limited thereto.

The second semiconductor chips 520a and 520b may include memory chips including memory circuits.

In some example embodiments, solder balls as the conductive connection members 550 may be respectively formed on lower substrate pads 514 of a lower surface of the second package substrate 510 of the upper package P2 by a solder ball attach process, and then, the upper package P2 may be mounted on the lower package P1 via the conductive connection members 550.

The conductive connection members 550 may be interposed between the lower package P1 and the upper package P2 to electrically connect them. A gap may be formed between the upper package P2 and the lower package P1 by the conductive connection members 550. The conductive connection members 550 formed on the lower substrate pads 514 of the second package substrate 510 of the upper package P2 may be bonded to the upper interposer pads 420 of the interposer 400.

Although it is not illustrated in the figures, an underfill member may be formed between the lower package P1 and the upper package P2. For example, while moving a dispenser nozzle along one side of the upper package P2, a liquid underfill aqueous solution may be dispensed into the gap between the lower package P2 and the upper package P1. For example, the aqueous underfill solution may include an epoxy material. The underfill aqueous solution may flow to the gap between the lower package P1 and the upper package P2 and then harden to form the underfill member.

Thus, the upper package P2 may be mounted on the lower package P1 at a board level and then, the underfill process between the lower package P1 and the upper package P2 may be performed to complete the semiconductor package of FIG. 1 with secured reliability.

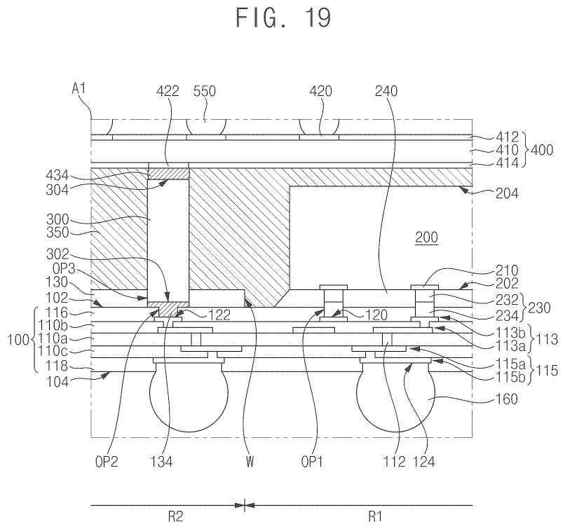

FIG. 19 is a cross-sectional view illustrating a portion of a semiconductor package in accordance with some example embodiments. FIG. 19 is an enlarged cross-sectional view corresponding to the ‘A1’ portion in FIG. 1. The semiconductor package may be the same as or substantially similar to the semiconductor package described with reference to FIGS. 1 to 3 except for configurations of bonding pads. Thus, same reference numerals may be used to refer to the same or like elements and any further repetitive explanation concerning the above elements will be omitted.

Referring to FIG. 19, a lower package P1 of a semiconductor package 11 may include a first package substrate 100 that has a first upper protective layer 116 having first openings OP1 exposing a plurality of first substrate pads 120 in a first region R1 and second openings OP2 exposing a plurality of second substrate pads 122 in a second region R2. A second upper protective layer 130 may be provided on the first upper protective layer 116 in the second region R2 of the first package substrate 100. The second upper protective layer 130 may have third openings OP3 exposing the second openings OP2.

In some example embodiments, bonding pads 134 may be provided in the second openings OP2 of the first upper protective layer 116 respectively. The conductive posts 132 of FIG. 2 are omitted, and the bonding pads 134 may completely fill the second openings OP2 and contact the second substrate pads 122, respectively. The bonding pads 134 may fill lower portions of the third openings OP3 respectively. The bonding pads 134 may include a metal material such as solder. A first end portion 302 of a conductive connection pin 300 may be provided to be received within the third opening OP3 of the second upper protective layer 130. The conductive connection pins 300 may be bonded to the bonding pads 134, respectively, by a reflow process.

Hereinafter, a process of forming the bonding pads and the conductive connection pins will be described.

A solder material may be injected into the second openings OP2 and the third openings OP3 of the first upper protective layer 116 of FIG. 8 and a reflow process may be performed to form bonding pads 134, respectively.

The bonding pad 134 may be formed to completely fill the second opening OP2 and may contact the second substrate pad 122. In addition, the bonding pad 134 may be formed to fill a lower portion of the third opening OP3.

The conductive connection pins 300 having a selected aspect ratio may be formed, and the conductive connection pins 300 may be bonded onto the bonding pads 134 respectively.

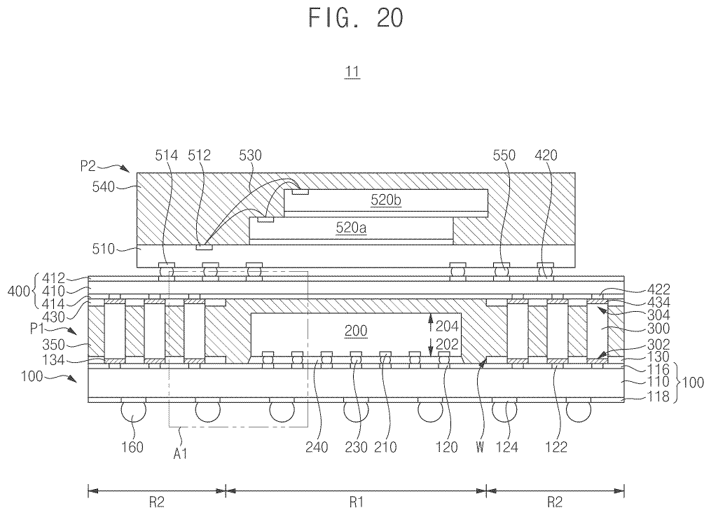

FIG. 20 is a plan view illustrating a semiconductor package in accordance with some example embodiments. FIG. 29 is an enlarged cross-sectional view illustrating portion ‘A1’ in FIG. 20. The semiconductor package is the same as and/or substantially similar to the semiconductor package described with reference to FIGS. 1 to 3 except for configurations of a lower insulating layer and bonding members on a lower surface of an interposer. Thus, same reference numerals may be used to refer to the same or like elements and any further repetitive explanation concerning the above elements will be omitted.

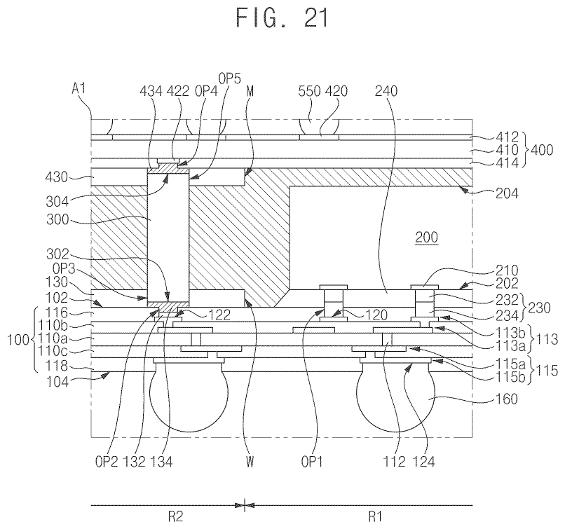

Referring to FIGS. 20 and 21, an interposer 400 of a lower package P1 may have a third region corresponding to a first region R1 of a package substrate 100 and a fourth region corresponding to a second region R2 of the first package substrate 100. The interposer 400 may include a lower insulating layer 414 having fourth openings OP4 that respectively expose lower interposer pads 422 within the third region, and a lower protective layer 430 provided on the lower insulating layer 414 and having fifth openings OP5 that respectively expose the fourth openings OP4. The lower protective layer 430 may have a window M that expose the third region and may cover the entire fourth region of the interposer 400.

For example, each of the fourth openings OP1 may have a fourth diameter and each of the fifth openings OP5 may have a fifth diameter. The fifth diameter may be greater than the fourth diameter. The fourth diameter may be within a range of 25 μm to 60 μm, and the fifth diameter may be within a range of 40 μm to 90 μm. The lower protective layer 430 may include a photosensitive resin such as photo epoxy, a photosensitive polymer such as photosensitive polyimide (PSPI), photo solder resist (PSR), etc.

In some example embodiments, bonding members 434 may be provided within the fourth openings OP4 of the lower insulating layer 414 respectively. The bonding members 434 may completely fill the fourth openings OP4 and may contact the lower interposer pads 422, respectively. The bonding members 434 may fill lower portions of the fifth openings OP5 respectively. The bonding members 434 may include a metal material such as solder. A second end portion 304 of the conductive connection pin 300 may be provided to be received within the fifth opening OP5 of the lower protective layer 430. The conductive connection pins 300 may be respectively bonded to the bonding members 434 by a reflow process.

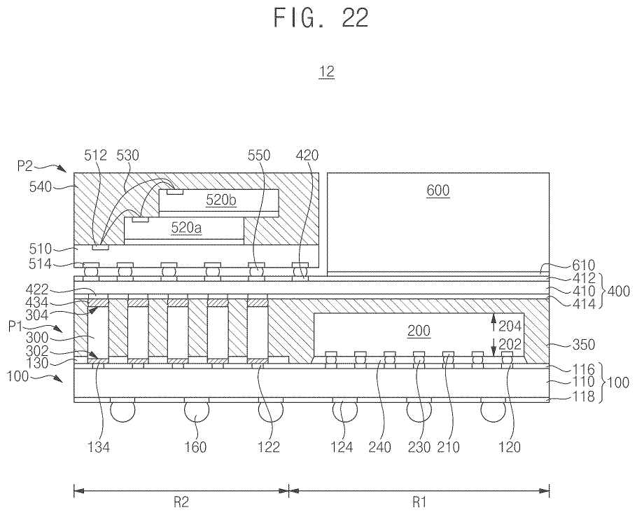

FIG. 22 is a cross-sectional view illustrating a semiconductor package in accordance with some example embodiments. The semiconductor package is the same as or substantially similar to the semiconductor package described with reference to FIGS. 1 to 3 except for configurations of an upper package and a heat dissipation block. Thus, same reference numerals may be used to refer to the same or like elements and any further repetitive explanation concerning the above elements will be omitted.

Referring to FIG. 22, a semiconductor package 12 may include a lower package P1, an upper package P2 stacked on the lower package P1 via conductive connecting members 550, and a heat dissipation block 600 disposed on the lower package P1.

In some example embodiments, the upper package P2 and the heat dissipation block 600 may be arranged to be spaced apart from each other on the lower package P1. The heat dissipation block 600 may be disposed on the first semiconductor chip 200, and the upper package P2 may be disposed on the plurality of conductive connection pins 300. The heat dissipation block 600 may be arranged to at least partially overlap the first semiconductor chip 200, and the upper package P2 may be arranged to overlap some of the plurality of conductive connection pins 300.

For example, the heat dissipation block 600 may be attached to an upper surface of the interposer 400 by an adhesive film 610 such as a non-conductive adhesive film (NCF). The heat dissipation block 600 may include a metal such as copper or a silicon material.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, high bandwidth memory (HBM) devices, or non-volatile memory devices such as flash memory devices, PRAM devices, MRAM devices, ReRAM devices, or the like.

According to some example embodiments, in a method of manufacturing a semiconductor package a package substrate is provided, the package substrate including a plurality of first substrate pads, a plurality of second substrate pads, and a first upper protective layer, the plurality of first substrate pads on an upper surface of the package substrate in a first region, the plurality of second substrate pads of the upper surface of the package substrate in a second region, and the first upper protective layer exposing the plurality of first substrate pads through first openings and exposing the plurality of second substrate pads through second openings. A second upper protective layer is formed on the first upper protective layer in the second region of the package substrate such that the second upper protective layer exposes the second openings through third openings. A plurality of bonding pads is formed in the third openings of the second upper protective layer respectively to be electrically connected to the plurality of second substrate pads. A semiconductor chip is arranged on the first upper protective layer in the first region of the package substrate to be electrically connected to the plurality of first substrate pads. Conductive connection pins are arranged on the plurality of bonding pads, respectively. An interposer is arranged on the package substrate such that the conductive connection pins are between the interposer and the package substrate and such that the interposer is electrically connected to the conductive connection pins. And a molding member is formed such that the molding member covers the semiconductor chip and the conductive connection pins between the package substrate and the interposer.

In some example embodiments, the method may further include forming conductive posts in the second openings of the first upper protective layer respectively such that the conductive posts respectively contact the plurality of second substrate pads. The plurality of bonding pads may be respectively provided on the conductive posts.

In some example embodiments, the forming the plurality of bonding pads may include forming the plurality of bonding pads such that the plurality of bonding pads completely fills the second openings and contact the plurality of second substrate pads, respectively.

In some example embodiments, the arranging the conductive connection pins may include accommodating lower end portions of the conductive connection pins in to the third openings of the second upper protective layer.

In some example embodiments, a diameter of each of the second openings may be within a range of 25 micrometers (μm) to 60 μm, and a diameter of each of the third openings may be within a range of 40 μm to 90 μm.

In some example embodiments, the plurality of bonding pads may include solder.

In some example embodiments, the method may further include arranging a plurality of bonding members between the conductive connection pins and lower interposer pads of the interposer, respectively.

In some example embodiments, the interposer may include a lower insulating layer and a lower protective layer, the lower insulating layer exposing the lower interposer pads through fourth openings and the lower protective layer on the lower insulating layer, and the lower protective layer exposing the fourth openings through fifth openings, and the plurality of bonding members may fill lower portions of the fifth openings, completely fill the fourth openings, and contact the lower interposer pads, respectively.

In some example embodiments, the semiconductor chip may include chip pads on a first surface, and the arranging the semiconductor chip may include arranging the semiconductor chip such that the first surface faces the package substrate, and mounting the semiconductor chip on the package substrate via conductive bumps that are formed on the chip pads.

In some example embodiments, the method may further include stacking an upper package on the interposer via conductive connecting members.

The foregoing is illustrative of some example embodiments and is not to be construed as limiting thereof. Although a few some example embodiments have been described, those skilled in the art will readily appreciate that many modifications are possible in some example embodiments without materially departing from the novel teachings and advantages of the present invention. Accordingly, all such modifications are intended to be included within the scope of some example embodiments as defined in the claims.

What is claimed is:

1. A semiconductor package, comprising:
a package substrate including a first upper protective layer exposing a plurality of first substrate pads and a plurality of second substrate pads, the plurality of first substrate pads on an upper surface of the package substrate in a first region and the plurality of second substrate pads on the upper surface of the package substrate in a second region;
a second upper protective layer on an upper surface of the first upper protective layer, the second upper protective layer in the second region of the package substrate and exposing the first region of the package substrate, the second upper protective layer including a plurality of bonding pads electrically connected to the plurality of second substrate pads;
a semiconductor chip on the first upper protective layer in the first region of the package substrate, the semiconductor chip electrically connected to the plurality of first substrate pads;
conductive connection pins respectively on the plurality of bonding pads;
an interposer over the package substrate such that the conductive connection pins are between the interposer and the package substrate, the interposer electrically connected to the conductive connection pins; and
a molding member between the package substrate and the interposer such that the molding member is covering the semiconductor chip and the conductive connection pins.

2. The semiconductor package of claim 1, wherein the first upper protective layer defines first openings and second openings such that the first upper protective layer exposes the plurality of first substrate pads through the first openings and exposes the plurality of second substrate pads through the second openings,
the second upper protective layer exposes the second openings through third openings, and
the plurality of bonding pads respectively fill lower portions of the third openings,.

3. The semiconductor package of claim 2, further comprising:
conductive posts filling lower portions of the second openings of the first upper protective layer and respectively contacting the plurality of second substrate pads, and
the plurality of bonding pads are respectively provided on the conductive posts.

4. The semiconductor package of claim 2, wherein the plurality of bonding pads completely fill the second openings and respectively contact the plurality of second substrate pads.

5. The semiconductor package of claim 2, wherein
a diameter of each of the second openings is within a range of 25 micrometers (μm) to 60 μm, and
a diameter of each of the third openings is within a range of 40 μm to 90 μm.

6. The semiconductor package of claim 1, wherein the plurality of bonding pads include solder.

7. The semiconductor package of claim 1, further comprising:
a plurality of bonding members respectively between the conductive connection pins and lower interposer pads of the interposer.

8. The semiconductor package of claim 7, wherein the interposer includes a lower insulating layer and a lower protective layer, the lower insulating layer respectively exposing the lower interposer pads through fourth openings and the lower protective layer on the lower insulating layer and exposing the fourth openings through fifth openings, and
the plurality of bonding members fill lower portions of the fifth openings, completely fill the fourth openings, and are in contact with the lower interposer pads, respectively.

9. The semiconductor package of claim 1, wherein the semiconductor chip has a first surface, the first surface including chip pads,
the first surface facing the package substrate, and
the semiconductor chip is mounted on the package substrate via conductive bumps that are respectively connected to the chip pads.

10. The semiconductor package of claim 1, further comprising:
an upper package on the interposer via conductive connecting members.

11. A semiconductor package, comprising:
a package substrate including a plurality of first substrate pads, a plurality of second substrate pads, and a first upper protective layer, the plurality of first substrate pads on an upper surface of the package substrate in a first region, the plurality of second substrate pads on the upper surface of the package substrate in a second region, and the first upper protective layer exposing the plurality of first substrate pads through first openings and exposing the plurality of second substrate pads through second openings;
a second upper protective layer on an upper surface of the first upper protective layer in the second region of the package substrate, the second upper protective layer exposing the second openings through third openings;
a plurality of bonding pads respectively in the third openings of the second upper protective layer, the plurality of bonding pads electrically connected to the plurality of second substrate pads;
a semiconductor chip on the first upper protective layer in the first region of the package substrate, the semiconductor chip electrically connected to the plurality of first substrate pads;
conductive connection pins respectively on the plurality of bonding pads;
an interposer over the package substrate such that the conductive connection pins are between the interposer and the package substrate, the interposer electrically connected to the conductive connection pins; and
a molding member between the package substrate and the interposer such that the molding member is covering the semiconductor chip and the conductive connection pins.

12. The semiconductor package of claim 11, further comprising:
conductive posts respectively within the second openings of the first upper protective layer and in contact with the plurality of second substrate pads,
wherein the plurality of bonding pads are respectively on the conductive posts.

13. The semiconductor package of claim 11, wherein the plurality of bonding pads completely fill the second openings and are respectively in contact with the plurality of second substrate pads.

14. The semiconductor package of claim 11, wherein lower end portions of the conductive connection pins are respectively within the third openings of the second upper protective layer.

15. The semiconductor package of claim 11, wherein
a diameter of each of the second openings is within a range of 25 micrometers (μm) to 60 μm, and
a diameter of each of the third openings is within a range of 40 μm to 90 μm.

16. The semiconductor package of claim 11, wherein the plurality of bonding pads include solder.

17. The semiconductor package of claim 11, further comprising:
a plurality of bonding members respectively between upper end portions of the conductive connection pins exposed by the molding member and lower interposer pads of the interposer.

18. The semiconductor package of claim 17, wherein the interposer includes a lower insulating layer exposing the lower interposer pads through fourth openings and a lower protective layer on the lower insulating layer, the lower protective layer exposing the fourth openings through fifth openings, and
the plurality of bonding members fill lower portions of the fifth openings, completely fill the fourth openings, and contact the lower interposer pads, respectively.

19. The semiconductor package of claim 11, further comprising:
an upper package on the interposer via conductive connecting members.

20. A semiconductor package, comprising:
a lower package;
an upper package; and
conductive connecting members connecting the upper package to the lower package, the lower package comprising
a package substrate including a plurality of first substrate pads, a plurality of second substrate pads, and a first upper protective layer, the plurality of first substrate pads on an upper surface of the package substrate in a first region, the plurality of second substrate pads on the upper surface of the package substrate in a second region, and the first upper protective layer exposing the plurality of first substrate pads through first openings and exposing the plurality of second substrate pads through second openings,
a second upper protective layer on the first upper protective layer in the second region of the package substrate, the second upper protective layer exposing the second openings through third openings,
a plurality of bonding pads respectively within the third openings and electrically connected to the plurality of second substrate pads,
a semiconductor chip on the first upper protective layer within the first region of the package substrate, the semiconductor chip electrically connected to the plurality of first substrate pads,
conductive connection pins respectively on the plurality of bonding pads,
an interposer over the package substrate such that the conductive connection pins are between the interposer and the package substrate, the interposer electrically connected to the conductive connection pins; and
a molding member between the package substrate and the interposer such that the molding member is covering the semiconductor chip and the conductive connection pins.
